(19) United States
(12) Patent Application Publication
(10) Pub. No.: US 2025/0263866 A1
(43) Pub. Date: Aug. 21, 2025

(54) GALLIUM NITRIDE SINGLE CRYSTAL SUBSTRATE AND METHOD FOR PRODUCING THE SAME

(71) Applicant: SUMITOMO CHEMICAL COMPANY, LIMITED, Tokyo (JP)

(72) Inventors: Takashi SATO, Ibaraki (JP); Tetsuji FUJIMOTO, Ibaraki (JP); Toshio KITAMURA, Ibaraki (JP); Masatomo SHIBATA, Ibaraki (JP)

(21) Appl. No.: 19/053,823

(22) Filed: Feb. 14, 2025

(30) Foreign Application Priority Data
Feb. 16, 2024 (JP) 2024-021690

(51) Int. Cl. C30B 29/40; C30B 25/20; C30B 33/08

(52) U.S. Cl. CPC C30B 29/406; C30B 25/20; C30B 33/08

(57) ABSTRACT

There is provided a gallium nitride single crystal substrate, which is a gallium nitride single crystal substrate having a diameter of 50 mm or more, with a low-index crystal plane closest to a main surface being (0001), and in which an average density of etch pits during etching applied to the main surface using an alkaline etching solution is less than 1×10⁶ cm⁻²; and in histograms of diameters of the etch pits in multiple different regions on the main surface, and among peaks appearing in the histograms, when a diameter of a first peak which is a smallest diameter is denoted as a, a diameter of a second peak which is a second smallest diameter is denoted as b, frequency of the first peak (the number of etch pits) is denoted as A, frequency of the second peak is denoted as B, the number of the etch pits constituting the first peak is denoted as α, and the number of the etch pits constituting the second peak is denoted as β, at least one of the following conditions (1), (2), and (3) is satisfied: (1) variation in a/b values in the multiple histograms is within ±5% of an average value. (2) variation in A/B values in the multiple histograms is within ±15% of an average value. (3) variation in α/β values in the multiple histograms is within ±30% of an average value.

### TECHNICAL FIELD

The present invention relates to a gallium nitride single crystal substrate and a method for producing the same.

### DESCRIPTION OF RELATED ART

For example, patent document 1 discloses a method for producing a gallium nitride single crystal substrate, the method including: preparing a base substrate composed of a single crystal of a group III nitride semiconductor, having a mirror-finished main surface, with a low index crystal plane being (0001) closest to the main surface; a first step of epitaxially growing a single crystal of a group III nitride semiconductor having a top surface in which (0001) is exposed directly on the main surface of the base substrate, and causing multiple recesses to generate on the top surface composed of an inclined interface other than (0001), gradually expanding the inclined interface upwardly toward the top of the main surface of the base substrate, causing (0001) to disappear from the top surface, and growing a first layer whose surface is composed only of the inclined interface; and a second step of epitaxially growing the single crystal of the group III nitride semiconductor on the first layer, causing the inclined interface to disappear, and growing a second layer having a mirror-finished surface, wherein in the first step, multiple recesses are formed on the top surface of the single crystal, and (0001) is caused to disappear, thereby forming multiple valleys and multiple peaks on the surface of the first layer.

Further for example, non-patent document 1 discloses a method for producing a gallium nitride single crystal substrate by a VAS (Void-Assisted Separation) method.

[Patent Document 1] JP 2020-33211 A.

[Non-patent Document 1] Jpn. J. Appl. Phys. Vol. 42 (2003) pp. L1-L3.

### SUMMARY OF THE INVENTION

An object of the present invention is to suppress cracks that occur during growth or machining when producing a gallium nitride single crystal substrate with low dislocation density.

According to one aspect of the present disclosure, there is provided a gallium nitride single crystal substrate,

which is a gallium nitride single crystal substrate having a diameter of 50 mm or more, with a low-index crystal plane closest to a main surface being (0001), and

in which an average density of etch pits during etching applied to the main surface using an alkaline etching solution is less than 1×10⁶ cm⁻²; and

in histograms of diameters of the etch pits in multiple different regions on the main surface, and among peaks appearing in the histograms, when a diameter of a first peak which is a smallest diameter is denoted as a, a diameter of a second peak which is a second smallest diameter is denoted as b, frequency of the first peak (the number of etch pits) is denoted as A, frequency of the second peak is denoted as B, the number of the etch pits constituting the first peak is denoted as α, and the number of the etch pits constituting the second peak is denoted as β, at least one of the following conditions (1), (2), and (3) is satisfied:
(1) variation in a/b values in the multiple histograms is within ±5% of an average value;
(2) variation in A/B values in the multiple histograms is within ±15% of an average value;
(3) variation in α/β values in the multiple histograms is within ±30% of an average value.

According to another aspect of the present disclosure, there is provided a method for producing a gallium nitride single crystal substrate, the method including the steps of:
(a) preparing a base substrate composed of a gallium nitride single crystal having (0001) that is a low-index crystal plane closest to a main surface, and having a uniform dislocation density distribution in a plane;
(b) epitaxially growing the gallium nitride single crystal on the main surface of the base substrate; and
(c) obtaining a gallium nitride single crystal substrate having a diameter of 50 mm, from the gallium nitride single crystal epitaxially grown in the step (b),

wherein in the step (b), the gallium nitride single crystal is epitaxially grown using only (0001) as a growth plane, without generating any inclined interface other than (0001) throughout an entire growth period; and

the gallium nitride single crystal substrate obtained in the step (c) is used as a new base substrate, and the steps (b) and (c) are repeated at least once or more.

According to the present disclosure, when producing a gallium nitride single crystal substrate with low dislocation density, cracks that occur during growth or machining can be suppressed.

### BRIEF DESCRIPTION OF THE DRAWINGS

FIG. 1 is a flowchart illustrating a method for producing a gallium nitride single crystal substrate according to one embodiment of the present invention.

FIG. 2A is a schematic cross-sectional view illustrating a part of a method for producing a gallium nitride single crystal substrate according to one embodiment of the present invention.

FIG. 2B is a schematic cross-sectional view illustrating a part of a method for producing a gallium nitride single crystal substrate according to one embodiment of the present invention.

FIG. 2C is a schematic cross-sectional view illustrating a part of a method for producing a gallium nitride single crystal substrate according to one embodiment of the present invention.

FIG. 3 is an SEM image illustrating an example of etch pits formed on the main surface of the gallium nitride single crystal substrate according to one embodiment of the present invention.

FIG. 4 illustrates histograms of etch pit diameters for VAS substrate.

FIG. 5 illustrates histograms of etch pit diameters for the substrate of example 1.

FIG. 6 illustrates histograms of etch pit diameters for the substrate of comparative example 1.

### DETAILED DESCRIPTION OF THE INVENTION

### Findings Obtained by the Inventors

First, the findings obtained by the inventors will be described.

It is known that when the c-plane of a gallium nitride (GaN) single crystal substrate is etched with, for example, an alkaline etching solution, etch pits corresponding to dislocations are formed. Further, a method for identifying the type of dislocation (edge, mixture, screw) based on the size (diameter) of the etch pits is also known to those skilled in the art. However, this method is not necessarily universally applicable. The size of the etch pits formed by alkaline etching corresponds to the size of the strain of a crystal lattice around a dislocation core. This is because the size of an etch pit depends not only on the type of dislocation, but also on the impurities trapped in the dislocation, the precipitates on the dislocation, the distance between the dislocation and other nearby dislocations, and so on.

For the reason described above, although it is difficult to identify the type of dislocation (edge, mixed, screw) based on the size of the etch pit, it can be said that dislocations that form large etch pits also have a large strain field around the dislocation core. Dislocations having a large strain field are likely to have a large Burgers vector, and such dislocations become hollow-core micropipe defects, and likely to become anomalous diffusion paths for impurities.

The size of the etch pit also depends greatly on etching conditions. Therefore, it is meaningless to discuss the absolute value of the size of the etch pit. However, among various types of the etch pits of different sizes detected by etching, the smallest etch pit is highly likely to correspond to an edge dislocation having a smallest strain field around the dislocation core. Therefore, the inventors have found a technique for determining the presence or absence of dislocation defects that adversely affect the properties of the device fabricated on a gallium nitride single crystal substrate, by examining a histogram of etch pit diameters and using the diameter of the smallest peak that appears in the histogram as a standard to examine the diameters and number of other etch pits. Then, when the diameter of a standard etch pit is taken as a, it was found that an etch pit having a diameter exceeding 4 a corresponds to a dislocation having accumulated the above-described large strain, and that such a dislocation is highly likely to have an adverse effect on the properties of the device.

Further, as described in patent document 1, when the dislocation density is reduced by forcibly changing the propagation direction of dislocations by means of a growth (hereinafter also referred to as 3D growth) with an inclined interface as a growth plane to annihilate dislocations, it was found that the type and density of the dislocations are likely to be varied in the plane, although the dislocation density of an entire substrate is reduced. When the type and density of the dislocations are varied in the plane, a large stress field is formed locally, making it easier for cracks to be introduced into the crystal.

The inventors have conducted extensive research into the relationship between the histogram of the diameters of etch pits formed by alkaline etching and the occurrence of cracks. As a result, when a histogram of diameters is created for each of multiple different regions in the plane, and the diameter of the first peak, which is the smallest diameter, is denoted as a, the diameter of the second peak, which is the second smallest diameter, is denoted as b, the frequency of the first peak (the number of etch pits) is denoted as A, the frequency of the second peak is denoted as B, the number of etch pits constituting the first peak is denoted as α, and the number of etch pits constituting the second peak is denoted as β, it has been found that when the variations in the a/b, A/B or α/β values in multiple histograms fall within a predetermined range, the occurrence of cracks can be dramatically reduced.

Further, the inventors have conducted extensive research into a method for producing a substrate having the above-described uniform in-plane histogram (in other words, a substrate having uniformly reduced dislocations in the plane). As a result, it is found that a substrate having the uniform in-plane histogram can be produced using a substrate with a uniform in-plane dislocation density distribution as a starting seed substrate by causing a growth (hereinafter, also referred to as 2D growth) of a gallium nitride single crystal, using only (0001) as a growth plane without generating any inclined interface other than (0001), and further by causing generational growth (details will be described later) without allowing a thick film to grow all at once, throughout an entire growth period.

### One Embodiment of the Present Invention

Hereinafter, one embodiment of the present invention will be described with reference to the drawings.

Hereinafter, in a GaN crystal having a wurtzite structure, <0001> axis is referred to as “c-axis” and (0001) is referred to as “c-plane”. (0001) is sometimes referred to as “+c plane (gallium polar plane)” and (000-1) is sometimes referred to as “−c plane (nitrogen (N) polar plane).” Further, <1-100> axis is referred to as “m-axis” and {1-100} is referred to as “m-plane.” The m-axis may also be written as <10-10> axis. Further, <11-20> axis is referred to as “a-axis” and {11-20} is referred to as “a-plane”.

### (1) Method for Producing a Gallium Nitride Single Crystal Substrate

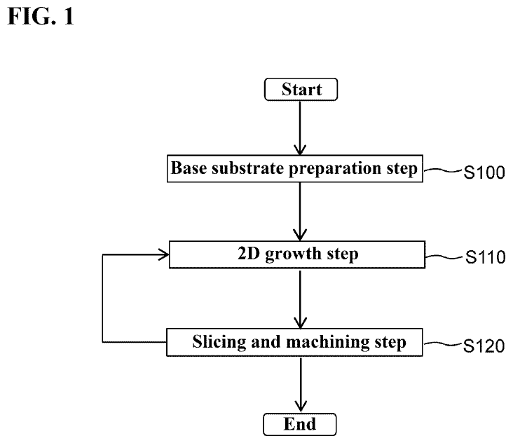

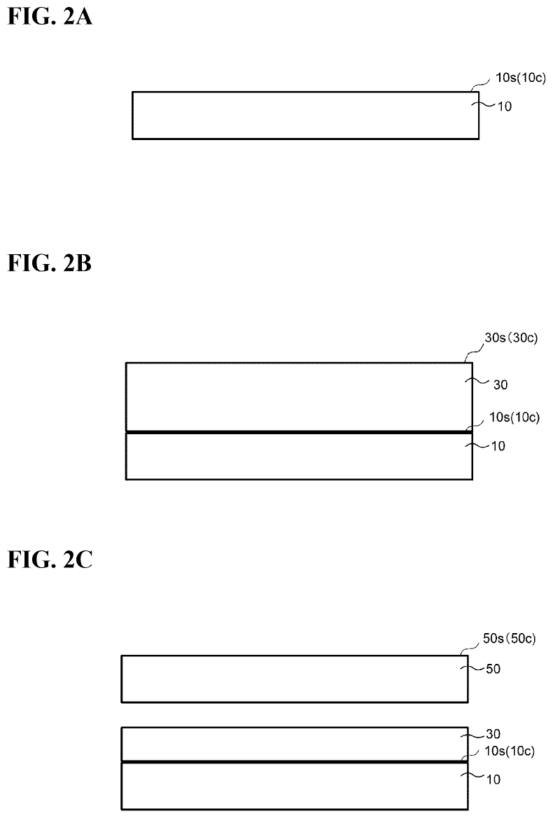

The method for producing a gallium nitride single crystal substrate according to this embodiment will be described with reference to FIG. 1 and FIGS. 2A to 2C. FIG. 1 is a flowchart illustrating a method for producing a gallium nitride single crystal substrate according to this embodiment. FIGS. 2A to 2C are schematic cross-sectional views illustrating a part of the method for producing a gallium nitride single crystal substrate according to this embodiment.

As illustrated in FIG. 1, the method for producing a gallium nitride single crystal substrate according to this embodiment includes, for example, a base substrate preparation step S100, a 2D growth step S110, and a slicing and machining step S120.

### S100: Base Substrate Preparation Step

As illustrated in FIG. 2A, in the base substrate preparation step S100, a base substrate 10 is prepared, which is composed of gallium nitride single crystal and in which a low-index crystal plane closest to a main surface 10s is (0001) (c-plane 10c) and the main surface 10s has a uniform in-plane dislocation density distribution. Specifically, it is preferable to prepare the base substrate 10 composed of gallium nitride single crystal by the VAS (Void-Assisted Separation) method described in non-patent document 1. A GaN substrate produced by the VAS method is characterized in the uniform in-plane dislocation density distribution, but c-plane warping occurs in the crystal such that the main surface 10s side is a concave surface. In order to fabricate a substrate having a uniform distribution of dislocation species, which is a feature of the gallium nitride single crystal substrate according to this embodiment, dislocations in the base substrate 10, which serves as a starting substrate, must not have undergone a 3D growth process such as ELO (Epitaxial Lateral Overgrowth), and dislocations must not accumulate locally, i.e., dislocations must be uniformly distributed in the plane. The VAS method is a suitable means for obtaining such a substrate, but the substrate produced by the VAS method has a fair amount of c-plane warping, and the size of this warping is in a trade-off relationship with the in-plane uniformity of dislocation density. In this embodiment, emphasis is placed on the in-plane uniformity of dislocation density, and the c-plane warping in the base substrate 10 is tolerated by taking measures to alleviate the c-plane warping in the subsequent crystal growth step (for example, the generational growth described below).

The base substrate 10 may be a substrate doped with a dopant such as germanium (Ge), silicon (Si), or oxygen (O), or may be a so-called undoped substrate that is not intentionally doped with a dopant.

### S110: 2D Growth Step

In the 2D growth step S110, on the main surface 10s of the base substrate 10 prepared in the base substrate preparation step S100, a single crystal of GaN is epitaxially grown with the c-plane 30c as a growth plane, as illustrated in FIG. 2B. Specifically, for example, by supplying GaCl gas and NH₃ gas to the heated base substrate 10 by the HVPE method, epitaxial growth is caused directly on the main surface 10s of the base substrate 10 to grow a growth layer 30.

At this time, depending on the growth conditions, as described in patent document 1, an inclined interface other than the c-plane may be generated on the growth surface, resulting in 3D growth. In the epitaxial crystal growth, there are three types of crystal growth modes in the initial stage of the growth, and these modes are changed depending on the crystal growth conditions. Of the above three modes, the VW (Volmer-Weber) mode and the SK (Stranski-Krastanov) mode are growth modes that induce 3D growth. In contrast, in the 2D growth step S110, it is necessary to epitaxially grow the GaN single crystal (i.e., grow it in 2D) using only the c-plane as a growth plane throughout an entire growth period, without generating any inclined interfaces other than the c-plane. To achieve the 2D growth, the crystal growth conditions can be adjusted to produce an FM (Frank-van der Merwe) mode, which is different from the above growth mode.

In the 3D growth, the propagation direction of dislocations is forcibly bent and locally accumulated, and therefore multiple dislocations are combined with each other to efficiently reduce the dislocation density, and meanwhile dislocations with large Burgers vectors are likely to occur, resulting in dislocation species with various crystal strains being scattered in the substrate plane. In such a region, a large local stress field is formed, which may cause cracks to occur during crystal growth or cooling.

In the 2D growth, the propagation direction of dislocations is not forcibly bent, but in the process of growing the crystal thicker, there is a certain probability that propagating dislocations that are inclined in a direction of travel will meet and disappear, or they will form dislocation loops and stop propagating, thus gradually reducing the dislocation density.

Thus, although the 2D growth requires more time to reduce dislocations than the 3D growth, dislocations can be uniformly reduced in the plane because there is no change in the propagation direction of dislocations or no forced combining of dislocations. Another advantage is that dislocations with large Burgers vectors, which are the result of combining of a large number of dislocations, are less likely to occur.

In the 2D growth step S110, the growth layer 30 is grown under predetermined growth conditions so that the crystal growth proceeds in the FM mode. As a growth condition in this embodiment, for example, the growth temperature is preferably set to, for example, 980° C. or more and 1200° C. or less. Further, in the 2D growth step S110, the ratio of the supply rate of NH₃ gas as a nitriding gas to the supply rate of GaCl gas as a group III source gas (hereinafter also referred to as the “V/III ratio”) is preferably set to, for example, 0.1 or more and 5 or less.

In the 2D growth step S110, a Si-doped GaN layer may be epitaxially grown as a growth layer 30 by supplying GaCl gas, NH₃ gas, and dichlorosilane (SiH₂Cl₂) gas as an n-type dopant gas to the base substrate 10, or a Ge-doped GaN layer may be epitaxially grown by supplying tetrachlorogermane (GeCl₄) gas as an n-type dopant gas instead of the SiH₂Cl₂ gas. As the growth layer 30, a GaN layer doped with iron (Fe), manganese (Mn), carbon (C), etc., may be epitaxially grown.

Other growth conditions in the 2D growth step S110 are, for example, as follows.

Growth pressure: 90 to 105 kPa, preferably 90 to 95 kPa.

GaCl gas partial pressure: 1.5 to 15 kPa.

N₂ gas flow rate/H₂ gas flow rate: 0 to 1.

In the 2D growth step S110, it is preferable that the thickness of the growth layer 30 is set to, for example, 3 mm or more and 20 mm or less. If the thickness of the growth layer 30 is less than 3 mm, there is a possibility that the effect of reducing dislocations may not be sufficiently obtained. In addition, the c-plane warping that occurs in the base substrate 10 is inherited by the growth layer 30 grown thereon, and therefore due to the growth of the growth layer 30 to a certain thickness or more, stress is generated in the crystal to straighten the warping and flatten the c-plane, and the size of the c-plane warping becomes gradually small. If the thickness of the growth layer 30 is less than 3 mm, there is a possibility that a sufficient stress for straightening the c-plane warping cannot be obtained. Further, in the subsequent slicing and machining step S120, it is difficult to obtain a GaN single crystal substrate with a sufficient thickness. In contrast, by setting the thickness of the growth layer 30 to 3 mm or more, dislocations can be uniformly reduced in the plane, and the c-plane warping can be small. Further, in the subsequent slicing and machining step S120, a GaN single crystal substrate with a sufficient thickness can be obtained. On the other hand, if the thickness of the growth layer 30 exceeds 20 mm, the force attempting to straighten the c-plane warping may cause excessive strain to accumulate in the crystal, leading to the proliferation of dislocations in the crystal or the generation of microcracks. Further, if the internal residual stress in the GaN crystal becomes large, crystal fracture is more likely to occur in the slicing and machining step S120. In contrast, by setting the thickness of the growth layer 30 to 20 mm or less, the internal residual stress of the GaN crystal can be reduced, and cracks and fractures can be suppressed.

### S120: Slicing and Machining Step

In the slicing and machining step S120, as illustrated in FIG. 2C, for example, the growth layer 30 is sliced along a cutting plane approximately parallel to the main surface 30s (c-plane 30c) of the growth layer 30 using a wire saw, etc. Thereby, at least one gallium nitride single crystal substrate 50 (also referred to as a substrate 50) having a diameter of 50 mm or more is obtained as an as-sliced substrate. At this time, it is preferable to slice the substrate 50 so that the thickness thereof is, for example, 300 μm or more and 500 μm or less.

As described above, due to the growth of the growth layer 30 to a certain thickness, stress is generated that attempts to straighten the c-plane warping during growth, and therefore the radius of curvature of the c-plane 50c of the substrate 50 cut out from the growth layer 30 becomes larger than the radius of curvature of the c-plane 10c of the base substrate 10. Further, the growth layer 30 is separated from the base substrate 10 by the slicing and machining step S120, and the growth layer 30 is released from the constraints imposed on the growth layer 30 from the base substrate 10 due to the c-plane warping, and therefore the radius of curvature of the c-plane 50c of the cut-out substrate 50 becomes further larger than before the base substrate 10 was separated. Thereby, the internal residual stress in the cut substrate 50 is also reduced.

Specifically, the radius of curvature of the c-plane 50c of the substrate 50 is, for example, preferably 60 m or more, and more preferably 80 m or more. Thereby, the variation in the off-angle θ of the c-axis relative to the normal on the major surface 50 of the substrate 50 (the maximum and minimum difference in the off-angle θ in the plane of the substrate) can be smaller than the variation in the off-angle of the c-axis of the base substrate 10.

Once the substrate 50 is obtained as an as-sliced substrate, both surfaces of the substrate 50 may be polished, for example, by a polishing device.

### Generational Growth

In this embodiment, the substrate 50 obtained in the slicing and machining step S120 is used as a new base substrate 10, and the 2D growth step S110 and the slicing and machining step S120 are repeated at least once or more (preferably four times or more). This type of growth is referred to as a generational growth in this specification. By performing such a generational growth rather than a growth caused all at once, the c-plane warp is alleviated each time the substrate 50 is cut out. This method enables to overcome the drawbacks of the substrate, even when the substrate with uniform dislocation density distribution is adopted at the expense of c-plane warping. Further, by performing generational growth, the internal residual stress of the resulting GaN crystal can be further reduced. By reducing the internal residual stress, the propagation direction of dislocations is more easily maintained even in the new 2D growth step S110 in which the substrate 50 is used as the base substrate 10, thereby making it easier to uniformly reduce dislocations in the plane. Specifically, by repeating the generational growth and increasing the cumulative growth thickness of the growth layer 30 to 12 mm or more, the dislocation density can be reduced to 5×10⁵ cm⁻³ or less. There is no particular upper limit in the number of times that the generational growth is performed, but from the viewpoint of efficiently producing a large-diameter GaN single crystal substrate, it is preferable to perform the growth 10 times or less, for example.

Through the above steps, the substrate 50 according to this embodiment is produced.

### Fabrication Step of a Semiconductor Stack and a Fabrication Step of a Semiconductor Device

After the substrate 50 is produced, for example, a semiconductor functional layer composed of a group III nitride semiconductor may be epitaxially grown on the substrate 50 to fabricate a semiconductor stack. After the semiconductor stack is fabricated, electrodes, etc., are formed on the semiconductor stack, and the semiconductor stack is diced to cut out chips of a predetermined size. In this way, a semiconductor device may be fabricated. Since the dislocations in the substrate 50 are uniformly reduced in the plane, the properties of the semiconductor device fabricated on the substrate 50 are uniform in the plane, thus improving reliability.

### (2) Gallium Nitride Single Crystal Substrate (Free-Standing Nitride Semiconductor Substrate, Nitride Crystal Substrate)

Next, the gallium nitride single crystal substrate 50 according to this embodiment will be described.

In this embodiment, the substrate 50 obtained by the above-described producing method is a free-standing substrate composed of single crystal GaN.

The diameter of the substrate 50 is, for example, 50 mm or more, and the thickness of the substrate 50 is, for example, 300 μm or more and 1 mm or less.

The conductivity of the substrate 50 is not particularly limited, but when the substrate 50 is used for producing a semiconductor device as a vertical Schottky barrier diode (SBD), the substrate 50 is, for example, an n-type, and the n-type impurity in the substrate 50 is, for example, Si or Ge, and the n-type impurity concentration in the substrate 50 is, for example, 1.0×10¹⁸ cm⁻³ or more and 1.0×10²⁰ cm⁻³ or less.

The substrate 50 has, for example, a main surface 50s which serves as an epitaxial growth plane. In this embodiment, the low-index crystal plane closest to the main surface 50s is, for example, a c-plane 50c.

The main surface 50s of the substrate 50 is, for example, mirror-finished, and the root-mean-square roughness RMS of the main surface 50s of the substrate 50 is, for example, less than 1 nm.

Further, in this embodiment, the impurity concentration in the substrate 50 obtained by the above-described producing method is lower than that in a substrate obtained by liquid phase growth such as the flux method or ammonothermal method.

Specifically, the hydrogen concentration in the substrate 50 is, for example, less than 1×10¹⁷ cm⁻³, and preferably 5×10¹⁶ cm⁻³ or less. Further, the oxygen concentration in the substrate 50 is, for example, 5×10¹⁶ cm⁻³ or less, and preferably 3×10¹⁶ cm⁻³ or less.

### Curving of the C-Plane and Variation in the Off-Angle

In this embodiment, since the substrate 50 is produced by generational growth, the radius of curvature of the c-plane 50c of the substrate 50 is larger than, for example, the radius of curvature of the c-plane 10c of the base substrate 10 used in the method for producing the substrate 50 described above. Specifically, the radius of curvature of the c-plane 50c of the substrate 50 is, for example, preferably 60 m or more, and more preferably 80 m or more.

In this embodiment, the upper limit of the radius of curvature of the c-plane 50c of the substrate 50 is not particularly limited, and is preferably as large as possible. When the c-plane 50c of the substrate 50 is substantially flat, the radius of curvature of the c-plane 50c may be considered to be infinite.

Further, in this embodiment, the large radius of curvature of the c-plane 50c of the substrate 50 allows the variation in the off-angle θ of the c-axis relative to the normal on main surface 50s of the substrate 50 to be smaller than the variation in the off-angle of the c-axis of base substrate 10.

Specifically, when an X-ray rocking curve measurement was performed for (0002) of the substrate 50 and the off-angle θ of the c-axis with respect to the normal on the main surface 50s was measured based on a diffraction peak angle of the (0002), the variation calculated from the maximum and minimum difference in the size of the off-angle θ within a diameter of 25 mm from the center of the main surface 50s is, for example, 0.024° or less, and preferably 0.018° or less.

In this embodiment, the lower limit of the variation in the off-angle θ of the c-axis of the substrate 50 is not particularly limited, and the smaller the better. When the c-plane 50c of the substrate 50 is substantially flat, the variation in the off-angle θ of the c-axis of the substrate 50 may be considered to be 0°.

Further, in this embodiment, since the curvature of the c-plane 50c is isotropically small with respect to the main surface 50s of the substrate 50, the radius of curvature of the c-plane 50c has little directional dependency.

Specifically, the difference between the radius of curvature of the c-plane 50c in the direction along the a-axis, as determined by the above-described measurement method, and the radius of curvature of the c-plane 50c in the direction along the m-axis, is, for example, 50% or less, and preferably 20% or less, of the larger of these radii of curvature.

### Dislocation Density

In this embodiment, by the above-described producing method, the dislocation density on the surface of substrate 50 is lower than the dislocation density on the main surface 10s of base substrate 10.

When the substrate 50 is produced using the base substrate 10 composed of high-purity GaN single crystal fabricated by the VAS method, the substrate 50 contains few non-radiative centers caused by foreign matters or point defects. Accordingly, when the main surface of the substrate 50 of the present application is observed using a multiphoton excitation microscope, etc., 95% or more (preferably 99% or more) of dark spots correspond to dislocations rather than non-radiative centers caused by foreign matters or point defects. The “multiphoton excitation microscope” is sometimes called a two-photon excitation microscope.

In this embodiment, by the above-described producing method, dislocations are uniformly reduced in the plane, and therefore regions with particularly high dislocation density due to dislocation concentration are not formed, and regions with low dislocation density are uniformly formed. Specifically, in this embodiment, when the main surface 50s of the substrate 50 is observed with a multiphoton excitation microscope in a field of view of 250 μm square and the dislocation density is calculated from a dark spot density, there is no region where the dislocation density exceeds 1×10⁶ cm⁻², and the region where the dislocation density is less than 5×10⁵ cm⁻² occupies 80% or more, preferably 90% or more, and more preferably 95% or more of the main surface 50s.

In other words, in this embodiment, the dislocation density averaged over an entire main surface 50s of the substrate 50 is, for example, less than 1×10⁶ cm⁻², preferably less than 5.5×10⁵ cm⁻², and more preferably 3×10⁵ cm⁻² or less.

### Etch Pit Histogram

When the main surface 50s of the substrate 50 is etched with an alkaline etching solution, etch pits as illustrated in FIG. 3 are formed. In this embodiment, the substrate 50 was immersed for 20 minutes in a molten liquid (temperature 470° C.) of a 1:1 mixture of potassium hydroxide (KOH) and sodium hydroxide (NaOH) to perform etching. Then, the main surface 50s of the substrate 50 after etching was observed using an SEM, and the diameter of each etch pit was calculated by image analysis. A histogram of etch pit diameters was created from the obtained data on the etch pit diameters. The etch pit diameter may be the maximum diameter of each etch pit region obtained by image analysis, or may be an equivalent circle diameter. In this embodiment, the diameter of the smallest peak (hereinafter also referred to as a first peak) among the peaks appearing in the histogram of etch pit diameters was standardized as a, and the horizontal axis was divided into classes in increments of 0.1 a. The vertical axis indicates the number (frequency) of the etch pits in a measurement area.

The average density (number per unit area) of the etch pits formed during etching applied to the main surface 50s of the substrate 50 of this embodiment under the above-described conditions, nearly matches the dislocation density determined by observation using the multiphoton excitation microscope. The size of the etch pits can be changed by adjusting etching conditions, but if they are present at too high a density, adjacent etch pits will overlap, making it difficult to measure the diameter of the etch pits, and therefore in order to perform a meaningful measurement, the average density of the etch pits is preferably less than 1×10⁶ cm⁻², more preferably less than 5.5×10⁵ cm⁻², and even more preferably 3×10⁵ cm⁻² or less. The histograms of the average density of the etch pits and the diameters of the etch pits are preferably measured from a region having an area of 1 mm² or more.

When the histogram of etch pit diameters is created for each of multiple different regions on the main surface 50s of the substrate 50, and among the peaks appearing in the histogram, the diameter of the first peak, which is the smallest diameter, is denoted as a, the diameter of the second peak, which is the second smallest diameter, is denoted as b, the frequency of the first peak (the number of etch pits) is denoted as A, the frequency of the second peak is denoted as B, the number of etch pits constituting the first peak is denoted as α, and the number of etch pits constituting the second peak is denoted as β, the substrate 50 of this embodiment satisfies at least one of the following conditions (1), (2), and (3):
(1) variation in a/b values in the multiple histograms is within ±5% of an average value.
(2) variation in A/B values in the multiple histograms is within ±15% of an average value.
(3) variation in α/β values in the multiple histograms is within ±30% of an average value.

The substrate 50 from which such a histogram is obtained has dislocations uniformly reduced in the plane, and is therefore unlikely to cause cracks to occur during crystal growth or machining. On the other hand, the substrate having variations exceeding the conditions (1), (2) and (3) has a large localized stress field, and is likely to cause cracks to occur during crystal growth or machining. In order to accurately determine the conditions (1), (2), and (3), it is preferable to create histograms of etch pit diameters in three or more (more preferably five or more) different regions on the main surface 50s.

The substrate 50 preferably satisfies two of the conditions (1), (2), and (3), and more preferably satisfies all of the conditions (1), (2), and (3). This allows the rate of crack occurrence to be more dramatically reduced during crystal growth or machining.

Further, the substrate 50 preferably satisfies at least one of the following conditions (4), (5) and (6), more preferably satisfies two of them, and particularly preferably satisfies all of them:
(4) difference between maximum and minimum values of a/b in the multiple histograms is 0.1 or less.
(5) difference between maximum and minimum values of A/B in the multiple histograms is 0.5 or less.
(6) difference between maximum and minimum values of α/β in the multiple histograms is 0.8 or less.

Also, the substrate 50 preferably satisfies at least one of the following conditions (7), (8) and (9), more preferably satisfies two of them, and particularly preferably satisfies all of them:
(7) standard deviation of a/b in the multiple histograms is 0.03 or less.
(8) standard deviation of A/B in the multiple histograms is 0.20 or less.
(9) standard deviation of β/α in the multiple histograms is 0.3 or less.

Also, the substrate 50 preferably satisfies at least one of the following conditions (10) and (11), and more preferably satisfies both of them:
(10) A/α is 0.5 or more, and more preferably 0.7 or more in the multiple histograms.
(11) B/β is 0.5 or more, and more preferably 0.7 or more in the multiple histograms.

Further, it is preferable that the number of the etch pits of the substrate 50 is 90% or more, and more preferably 95% or more in the multiple histograms.

In the substrate 50 of this embodiment, the total number of the etch pits having a diameter exceeding 4 a is preferably α/1000 or less. This can also be said to mean that there are substantially no etch pits having a diameter exceeding 4 a, but since large etch pits may be formed due to scratches or foreign matters on the substrate 50, the total number of the etch pits is expressed as α/1000 or less. In the substrate 50 of this embodiment, dislocations are less likely to combine with each other due to the above-described producing method, and therefore it can be said that there are substantially no dislocation species or dislocation accumulation regions that would generate large local stress. Accordingly, the occurrence of cracks during crystal growth or machining can be suppressed.

In substrate 50 of this embodiment, the total number of the etch pits having a diameter of 2 a or more is preferably 1/10 or less, and more preferably 1/100 or less of the number of the etch pits constituting the first peak. The etch pits having a diameter of 2 a or more may correspond to dislocations that generate large local stress, and therefore by setting the total number of the etch pits having a diameter of 2 a or more to 1/10 or less (more preferably 1/100 or less) of the number of the etch pits constituting the first peak, the occurrence of cracks can be suppressed.

In the substrate 50 of this embodiment, the number of the etch pits constituting the first peak is preferably 50% or more (more preferably 70% or more) of the total. In this embodiment, as described above, the dislocations are less likely to combine with each other, and therefore the proportion of dislocations with small strain fields is high, which suppresses the occurrence of cracks.

In the substrate 50 of this embodiment, when the frequency of the first peak is A, it is preferable that there are two peaks, the first peak and the second peak, that appear in the diameter histogram and have a frequency of A/10 or more. It can be said that the number of peaks appearing in the histogram of the etch pits corresponds to the number of component species of dislocation defects corresponding to the etch pits. Crystals in which many peaks are observed are not only characterized by simple edge or mixed dislocations, but also by a wide variety of impurities and point defects that are in combination with these dislocations. That is, they are crystals in which there is a high possibility that many impurity levels and defect levels are generated. It can be said that a large stress field occurs locally, and cracks are likely to occur during crystal growth or machining. In contrast, the crystal in which the histogram shows two peaks, the first peak and the second peak, with a frequency of A/10 or more, suggests that the only types of dislocations present in the crystal are simple edge dislocations and mixed dislocations. That is, it can be said that this is a substrate in which cracks are unlikely to occur during crystal growth or machining.

Further, the substrate 50 of this embodiment has a second peak in a diameter range of more than a and less than 2 a, and the number β of the etch pits constituting the second peak is preferably smaller than the number a of the etch pits constituting the first peak. The diameter of the etch pit constituting the second peak is in the range of more than a and less than 2 a. This means that it is highly likely that these etch pits correspond to a simple mixed dislocation. Also, the small number of etch pits constituting the second peak, in other words, the large number of etch pits constituting the first peak, means that the dislocations in the crystal are mainly composed of dislocations with little strain around the dislocation core. These features mean that the substrate 50 is a substrate in which cracks are unlikely to occur during crystal growth or machining.

### Other Embodiments

The embodiment of the present invention has been specifically described above. However, the present invention is not limited to the above embodiment, and various modifications can be made without departing from the spirit and scope of the present invention.

The above embodiment mainly shows a case where the substrate 50 is an n-type. However, the substrate 50 may be a p-type or may have semi-insulating properties. For example, when the substrate 50 is used to produce a semiconductor device such as a high electron mobility transistor (HEMT), the substrate 50 preferably has semi-insulating properties.

The above embodiment shows a case where the growth layer 30 is sliced using a wire saw in the slicing and machining step S120, but for example, an outer circumferential blade slicer, an inner circumferential blade slicer, an electric discharge machine, etc., may also be used.

### EXAMPLE

Next, examples of the present invention will be described. These examples are merely examples of the present invention, and the present invention is not limited to these examples.

### (1) Fabrication of a Gallium Nitride Single Crystal Substrate

Gallium nitride single crystal substrates of example 1 and comparative example 1 were fabricated as follows.

### [Fabrication Conditions for the Gallium Nitride Single Crystal Substrate in Example 1] (Base Substrate)

Material: GaN.

Fabrication method: VAS method.

Diameter: 2 inches.

Thickness: 400 μm.

Low-index crystal plane closest to the main surface: c-plane.

No pattern machining for the mask layer, etc., on the main surface.

Root mean square roughness RMS of the main surface: 2 nm.

Off-angle on the main surface: 0.4° in the m direction.

Radius of curvature of the main surface: 5 m.

Dislocation density of the main surface: 3×10⁶ cm⁻² (growth layer).

Material: GaN.

Growth method: HVPE, 2D growth.

Growth temperature: 980° C. to 1,200° C.

V/III ratio: 0.1 to 5.

Thickness of the growth layer: 3 mm (slicing conditions).

Thickness of the gallium nitride single crystal substrate: 400 μm (generational growth).

Number of generational growths: 4 times.

### [Fabrication Conditions for the Gallium Nitride Single Crystal Substrate in Comparative Example 1] (Base Substrate)

Same as example 1.

Material: GaN.

Growth method: HVPE, 3D growth.

First growth condition:

Growth temperature was 980° C. to 1,020° C., and V/III ratio was 2 to 20.

Thickness from the main surface of the base substrate to the surface of the first layer: 1 mm (second layer).

Material: GaN.

Growth method: HVPE, 2D growth.

Second growth condition:

Growth temperature was 1,050° C. to 1,080° C., and V/III ratio was 2 to 5.

Thickness from the main surface of the base substrate to the surface of the second layer: 2 mm (slicing condition).

Same as example 1.

### (Generational Growth)

In comparative example 1, generational growth was not performed.

### (2) Evaluation of the Etch Pit Histogram

The main surfaces of the base substrate (VAS substrate), the gallium nitride single crystal substrate of example 1, and the gallium nitride single crystal substrate of comparative example 1 were etched with an alkaline etching solution under the following conditions to form etch pits.

Etching solution: Alkaline melt consisting of 500 g KOH and 500 g NaOH.

Melting temperature: 470° C.

Immersion time: 20 minutes.

The main surface of the substrate formed with etch pits was observed using a SEM (SU5000, manufactured by Hitachi High-Technologies Corporation). A measurement field was 127 μm×95.3 μm (magnification 1000 times), and etch pits were measured by image analysis for an image (1143 μm×1048 μm) obtained by combining 9 horizontal×11 vertical (total of 99) SEM images. Specifically, using image processing software (Image J), the image was binarized, etch pit areas were filled in, and the larger one of the width and height of the etch pit area was calculated as the diameter of the etch pit. When the etch pit areas were filled in, areas showing small particles and linear pit areas caused by machining scratches, etc., were removed.

From the obtained data on the etch pit diameters, a histogram of etch pit diameters was created. In this example, among the peaks appearing in the histogram of etch pit diameters, the diameter of the peak (first peak) appearing on the smallest diameter side was standardized as 1, and the horizontal axis was divided into classes in increments of 0.1. The histograms were created in five regions: the center of the substrate (0 mm, 0 mm), the right side of the substrate (20 mm, 0 mm), the left side of the substrate (−20 mm, 0 mm), the top side of the substrate (0 mm, 20 mm), and the bottom side of the substrate (0 mm, −20 mm), with the center of the substrate as an origin, the left and right direction in a plan view as x direction, and the top and bottom direction in a plan view as y direction.

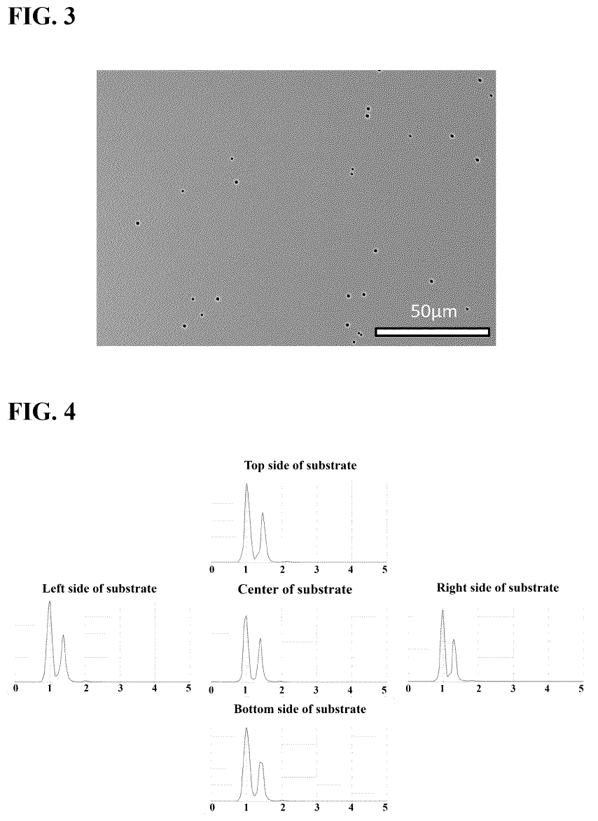

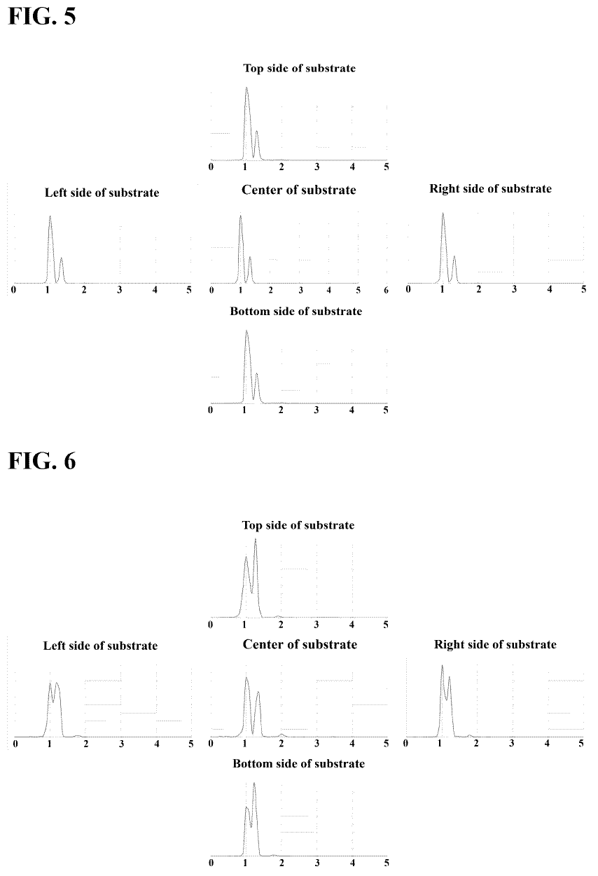

FIG. 4 illustrates a histogram of the VAS substrate, FIG. 5 illustrates a histogram of example 1, and FIG. 6 illustrates a histogram of comparative example 1. In each histogram, the horizontal axis indicates the normalized etch pit diameter, and the vertical axis indicates the number (frequency) of etch pits in the measurement area. Further, table 1 shows an average density of etch pits, a/b value, A/B value, α/β value, etc., in each histogram for the VAS substrate, example 1, and comparative example 1.

TABLE 1

| | | | | Variation from | | Variation from | | Variation from |
|---|---|---|---|---|---|---|---|---|
| Substrate | Properties | Measurement position | a/b | average value | A/B | average value | α/β | average value |
| VAS substrate | Average density | Center of substrate | 0.71 | −1.2% | 1.49 | −11.0% | 1.83 | 0.5% |
| | of etch pits | Right side of substrate | 0.77 | 6.9% | 1.71 | 2.1% | 1.75 | −4.0% |
| | 3.0 × 10⁵ cm⁻² | Left side of substrate | 0.72 | −0.1% | 1.71 | 1.8% | 1.83 | 0.5% |
| | | Top side of substrate | 0.68 | −5.4% | 1.56 | −6.9% | 1.65 | −6.6% |
| | | Bottom side of substrate | 0.72 | −0.1% | 1.91 | 14.0% | 1.99 | 9.6% |
| | Radius of curvature | Average value | 0.72 | — | 1.68 | — | 1.81 | — |
| | 5 m | Maximum value − | 0.09 | — | 0.42 | — | 0.34 | — |
| | | minimum value | | | | | | |
| | | Standard deviation | 0.03 | — | 0.14 | — | 0.11 | — |
| Example 1 | Average density | Center of substrate | 0.75 | −1.0% | 2.49 | 1.8% | 3.30 | −7.2% |
| | of etch pits | Right side of substrate | 0.75 | −1.0% | 2.48 | 1.4% | 3.38 | −2.8% |
| | 5.0 × 10⁵ cm⁻² | Left side of substrate | 0.75 | −1.0% | 2.53 | 3.5% | 3.38 | −2.8% |
| | | Top side of substrate | 0.77 | 1.5% | 2.41 | −1.3% | 3.62 | 7.0% |
| | | Bottom side of substrate | 0.77 | 1.5% | 2.31 | −5.4% | 3.58 | 5.8% |
| | Radius of curvature | Average value | 0.76 | — | 2.45 | — | 3.45 | — |
| | 60 m | Maximum value − | 0.02 | — | 0.22 | — | 0.32 | — |
| | | minimum value | | | | | | |
| | | Standard deviation | 0.01 | — | 0.08 | — | 0.13 | — |
| Comparative | Average density | Center of substrate | 0.73 | −8.4% | 1.32 | 34.6% | 1.57 | 7.0% |
| example 1 | of etch pits | Right side of substrate | 0.82 | 2.9% | 1.17 | 19.5% | 1.91 | 30.4% |
| | 5.0 × 10⁵ cm⁻² | Left side of substrate | 0.85 | 5.7% | 0.99 | 0.7% | 1.02 | −30.2% |
| | | Top side of substrate | 0.79 | −1.8% | 0.78 | −22.3% | 1.72 | 16.9% |
| | | Bottom side of substrate | 0.81 | 1.5% | 0.66 | −32.5% | 1.11 | −24.1% |
| | Radius of curvature | Average value | 0.80 | — | 0.98 | — | 1.47 | — |
| | 40 m | Maximum value − | 0.11 | — | 0.68 | — | 0.89 | — |
| | | minimum value | | | | | | |
| | | Standard deviation | 0.04 | — | 0.25 | — | 0.34 | — |

As illustrated in FIG. 4 and Table 1, in the VAS substrate, a histogram shape was uniform in the plane, and the above conditions (2) and (3) were satisfied. That is, although the VAS substrate has a relatively large average density of etch pits (in other words, dislocation density), it can be said to be a base substrate having a uniform in-plane distribution of dislocation density.

Further, as illustrated in FIG. 5 and Table 1, in the substrate of example 1, the histogram shape was uniform in the plane, and all of the above conditions (1), (2), and (3) were satisfied. Further, the average density of etch pits was smaller than that of the VAS substrate. That is, the substrate of example 1 can be said to be a substrate in which dislocations are uniformly reduced in the plane. Further, the variation from the average value of a/b value, A/B value, and α/β value of the substrate of example 1 was smaller than that of the VAS substrate.

Further, as illustrated in FIG. 6 and table 1, in the substrate of comparative example 1, the histogram shape was varied in the plane, and the above conditions (1), (2), and (3) were not satisfied. That is, the substrate of comparative example 1 can be said to be a substrate in which the dislocation density was reduced, but the density and type of dislocations were varied in the plane.

Table 2 shows the occurrence rates of cracks (growth cracks) occurring during the preparation of the substrate and cracks (machining cracks) occurring during machining of the substrate, that is, the VAS substrate, the substrate of example 1, and the substrate of comparative example 1. As shown in table 2, it can be said that the occurrence rates of cracks can be reduced for a substrate having higher in-plane uniformity of the histogram.

TABLE 2

| Substrate | Growth cracks | Machining cracks | Total |
|---|---|---|---|
| VAS substrate | 5% | 5% | 10% |
| Example 1 | 1% | 1% | 2% |
| Comparative | 20% | 30% | 50% |
| example 1 | | | |

### (3) Evaluation of the Radius of Curvature of the C-Plane

The radius of curvature of the c-plane of the base substrate (VAS substrate), the substrate of example 1, and the substrate of comparative example 1 was measured. As a result, the VAS substrate was 5 m, the substrate of example 1 was 60 m, and the substrate of comparative example 1 was 40 m.

As described above, it was confirmed that by using the VAS substrate having a uniform in-plane dislocation density distribution as a base substrate and repeating 2D growth and generational growth, the substrate having uniformly reduced dislocations in the plane could be produced. Further, it was confirmed that the rate of crack occurrence could be reduced for the substrate having higher in-plane histogram uniformity. Further, it was confirmed that the substrate of example 1, which underwent repeated generational growth, had a larger radius of curvature of the c-plane than the VAS substrate, which was the starting seed substrate, and than the substrate of comparative example 1, which did not undergo generational growth.

### Preferable Aspect of the Present Invention

Preferable aspects of the present invention will be described below.

### (Supplementary Description 1)

A gallium nitride single crystal substrate,

which is a gallium nitride single crystal substrate having a diameter of 50 mm or more, with a low-index crystal plane closest to a main surface being (0001), and

in which an average density of etch pits during etching applied to the main surface using an alkaline etching solution is less than 1×10⁶ cm⁻²; and

in histograms of diameters of the etch pits in multiple different regions on the main surface, and among peaks appearing in the histograms, when a diameter of a first peak which is a smallest diameter is denoted as a, a diameter of a second peak which is a second smallest diameter is denoted as b, frequency of the first peak (the number of etch pits) is denoted as A, frequency of the second peak is denoted as B, the number of the etch pits constituting the first peak is denoted as α, and the number of the etch pits constituting the second peak is denoted as β, at least one of the following conditions (1), (2), and (3) is satisfied:
(1) variation in a/b values in the multiple histograms is within ±5% of an average value.
(2) variation in A/B values in the multiple histograms is within ±15% of an average value.
(3) variation in α/β values in the multiple histograms is within ±30% of an average value.

### (Supplementary Description 2)

The gallium nitride single crystal substrate according to supplementary description 1, which satisfies two of the conditions (1), (2), and (3).

### (Supplementary Description 3)

The gallium nitride single crystal substrate according to supplementary description 1, which satisfies all of the conditions (1), (2), and (3).

### (Supplementary Description 4)

The gallium nitride single crystal substrate according to supplementary description 1, which satisfies at least any one of the following conditions (4), (5), and (6):
(4) difference between maximum and minimum values of a/b in the multiple histograms is 0.1 or less.
(5) difference between maximum and minimum values of A/B in the multiple histograms is 0.5 or less.
(6) difference between maximum and minimum values of α/β in the multiple histograms is 0.8 or less.

More preferably, two of the conditions (4), (5) and (6) are satisfied, and particularly preferably, all of the conditions (4), (5) and (6) are satisfied.

### (Supplementary Description 5)

The gallium nitride single crystal substrate according to supplementary description 1, which satisfies at least any one of the following conditions (7), (8), and (9):
(7) standard deviation of a/b in the multiple histograms is 0.03 or less.
(8) standard deviation of A/B in the multiple histograms is 0.20 or less.
(9) standard deviation of β/α in the multiple histograms is 0.3 or less.

More preferably, two of the conditions (7), (8), and (9) are satisfied, and particularly preferably, all of the conditions (7), (8), and (9) are satisfied.

### (Supplementary Description 6)

The gallium nitride single crystal substrate according to supplementary description 1, which satisfies at least one of the following conditions (10) and (11):

(10) A/α is 0.5 or more, and more preferably 0.7 or more in the multiple histograms.

(11) B/β is 0.5 or more, and more preferably 0.7 or more in the multiple histograms.

More preferably, both of the conditions (10) and (11) are satisfied.

### (Supplementary Description 7)

The gallium nitride single crystal substrate according to supplementary description 1, wherein in the multiple histograms, α+β represents 90% or more of a total number of etch pits.

### (Supplementary Description 8)

The gallium nitride single crystal substrate according to supplementary description 1, wherein a total number of etch pits having a diameter exceeding 4 a is α/1000 or less in the histogram.

### (Supplementary Description 9)

The gallium nitride single crystal substrate according to supplementary description 1, wherein a radius of curvature of (0001) is 60 nm or more.

### (Supplementary Description 10)

The gallium nitride single crystal substrate according to any one of supplementary descriptions 1 to 9, wherein an average density of etch pits and the histogram are measured from a region having an area of 1 mm² or more.

### (Supplementary Description 11)

A method for producing a gallium nitride single crystal substrate, the method including the steps of:
(a) preparing a base substrate composed of a gallium nitride single crystal having (0001) that is a low-index crystal plane closest to a main surface, and having a uniform dislocation density distribution in a plane;
(b) epitaxially growing the gallium nitride single crystal on the main surface of the base substrate; and
(c) obtaining a gallium nitride single crystal substrate having a diameter of 50 mm, from the gallium nitride single crystal epitaxially grown in the step (b),

wherein in the step (b), the gallium nitride single crystal is epitaxially grown using only (0001) as a growth plane, without generating any inclined interface other than (0001) throughout an entire growth period; and

the gallium nitride single crystal substrate obtained in the step (c) is used as a new base substrate, and the steps (b) and (c) are repeated at least once or more.

### (Supplementary Description 12)

The method for producing a gallium nitride single crystal substrate according to supplementary description 11, wherein the base substrate prepared in the step (a) is a substrate fabricated by a VAS method.

### (Supplementary Description 13)

The method for producing a gallium nitride single crystal substrate according to supplementary description 11, wherein in the step (b), the gallium nitride single crystal is grown to at least 3 mm or more.

### (Supplementary Description 14)

The method for producing a gallium nitride single crystal substrate according to claim 11, wherein each time the steps (b) and (c) are repeated, the dislocation density of the obtained gallium nitride single crystal substrate is reduced compared to that of the base substrate, and a radius of curvature of (0001) is larger than that of the base substrate.

1. A gallium nitride single crystal substrate,
which is a gallium nitride single crystal substrate having a diameter of 50 mm or more, with a low-index crystal plane closest to a main surface being (0001), and
in which an average density of etch pits during etching applied to the main surface using an alkaline etching solution is less than 1×10⁶ cm⁻²; and
in histograms of diameters of the etch pits in multiple different regions on the main surface, and among peaks appearing in the histograms, when a diameter of a first peak which is a smallest diameter is denoted as a, a diameter of a second peak which is a second smallest diameter is denoted as b, frequency of the first peak is denoted as A, frequency of the second peak is denoted as B, the number of the etch pits constituting the first peak is denoted as α, and the number of the etch pits constituting the second peak is denoted as β, at least one of the following conditions (1), (2), and (3) is satisfied:
(1) variation in a/b values in the multiple histograms is within ±5% of an average value.
(2) variation in A/B values in the multiple histograms is within ±15% of an average value.
(3) variation in α/β values in the multiple histograms is within ±30% of an average value.

2. The gallium nitride single crystal substrate according to claim 1, which satisfies two of the conditions (1), (2), and (3).

3. The gallium nitride single crystal substrate according to claim 1, which satisfies all of the conditions (1), (2), and (3).

4. The gallium nitride single crystal substrate according to claim 1, wherein in the histogram, a total number of etch pits having a diameter exceeding 4 a is α/1000 or less.

5. The gallium nitride single crystal substrate according to claim 1, wherein a radius of curvature of (0001) is 60 m or more.

6. The gallium nitride single crystal substrate according to claim 1, wherein an average density of etch pits and the histogram are measured from a region having an area of 1 mm² or more.

7. A method for producing a gallium nitride single crystal substrate, the method comprising the steps of:
(a) preparing a base substrate composed of a gallium nitride single crystal having (0001) that is a low-index crystal plane closest to a main surface, and having a uniform dislocation density distribution in a plane;
(b) epitaxially growing the gallium nitride single crystal on the main surface of the base substrate; and
(c) obtaining a gallium nitride single crystal substrate having a diameter of 50 mm, from the gallium nitride single crystal epitaxially grown in the step (b),
wherein in the step (b), the gallium nitride single crystal is epitaxially grown using only (0001) as a growth plane, without generating any inclined interface other than (0001) throughout an entire growth period; and
the gallium nitride single crystal substrate obtained in the step (c) is used as a new base substrate, and the steps (b) and (c) are repeated at least once or more.
